(19) United States
(12) Patent Application Publication
(10) Pub. No.: US 2009/0168583 A1
(43) Pub. Date: Jul. 2, 2009

(54) Internal voltage generator of semiconductor memory device

(75) Inventors: Jae-Kwan Kwon, Kyoungki-do (KR); Jee-Yul Kim, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 12/157,286

(22) Filed: Jun. 9, 2008

(30) Foreign Application Priority Data
Dec. 26, 2007 (KR) 2007-0137429

(51) Int. Cl. G11C 5/14

(52) U.S. Cl. 365/226

(57) ABSTRACT

An internal voltage generator of a semiconductor memory device generates pumping voltages (VPP, VBB, etc.) as internal voltages, which is capable of improving a charge pumping scheme. The internal voltage generator includes a plurality of charge pumping units for generating a pumping voltage by performing a charge pumping operation according to a plurality of pumping enable signals, and a pumping controller for controlling a number of the pumping enable signals to be activated according to a level of a fed-back pumping voltage.

### CROSS-REFERENCE(S) TO RELATED APPLICATIONS

The present invention claims priority to Korean patent application number 10-2007-0137429, filed on Dec. 26, 2007, which is incorporated by reference in its entirety.

### BACKGROUND OF THE INVENTION

The present invention relates to an internal voltage generator of a semiconductor memory device and, more particularly, to an internal voltage generator for generating a high voltage (VPP) (which is higher than a supply voltage (VDD)) or a negative voltage (VBB) (which is lower than a ground voltage (VSS)) by a charge pumping scheme.

In general, a semiconductor memory device externally receives voltages, such as a supply voltage (VDD) and a ground voltage (VSS), and generates an internal voltage, such as a high voltage (VPP) which is higher than the supply voltage (VDD) or a negative voltage (VBB) which is lower than the ground voltage (VSS) using the voltage.

Hereinafter, a conventional internal voltage generator of a semiconductor memory device will be described.

FIG. 1 is a view showing a conventional internal voltage generator for generating a pumping voltage in a semiconductor memory device.

As shown in FIG. 1, the conventional internal voltage generator includes a pumping controller 110 and a plurality of charge pumping units 120 to 180.

The pumping controller 110 compares a fed-back pumping voltage ⅓*VPP with a reference voltage VREF to generate a pumping enable signal PUMP_EN. When a pumping voltage VPP is fed-back to the pumping controller 110, the level of the voltage is lowered through the voltage division (e.g., feedback into ⅓*VPP). The reason for this is that since the pumping voltage VPP is higher than the supply voltage (VDD), the pumping voltage VPP having such a level makes it difficult to perform a comparison operation in relation to other voltages.

If the fed-back pumping voltage ⅓*VPP is lower than the reference voltage VREF, the pumping controller 110 enables the pumping enable signal PUMP_EN to be output such that the charge pumping units 120 to 180 can perform a pumping operation. The reason for this is that if the fed-back pumping voltage ⅓*VPP is lower than the reference voltage VREF, the level of the pumping voltage VPP is not high enough. Meanwhile, if the fed-back pumping voltage ⅓*VPP is higher than the reference voltage VREF, the level of the pumping voltage VPP is high enough so the pumping controller 110 disables the pumping enable signal PUMP_EN.

For reference, the pumping enable signal PUMP_EN can be designed to be enabled in a ‘high’ or ‘low’ state. It should be noted that the important thing is the condition for enabling the pumping enable signal PUMP_EN, and it is not important to determine the logic level, i.e., the ‘high’ or ‘low’ state, of the enabled pumping enable signal PUMP_EN.

When the pumping enable signal PUMP_EN is enabled, the charge pumping units 120 to 180 perform the pumping operation to raise the level of the pumping voltage VPP. When the pumping enable signal PUMP_EN is disabled, the charge pumping units 120 to 180 do not perform the pumping operation.

As is well known in the art, each charge pumping unit 120 to 180 may include an oscillator, a control circuit and a charge pump. The oscillator generates a periodic signal in response to the pumping. enable signal PUMP_EN. The control circuit outputs a pump driving signal in response to the periodic signal from the oscillator. The charge pump performs charge pumping in response to the pump driving signal. The charge pumping units 120 to 180 including such parts can be easily designed by those skilled in the art, so detailed description about the parts in the charge pumping unit will be omitted.

In a case of a dynamic random access memory (DRAM), as shown in FIG. 1, a plurality of charge pumping units 120 to 180 are used. As the DRAM becomes highly integrated, the amount of the high voltage VPP to be used is increased, so it is necessary to generate sufficient (charge) amount of the high voltage VPP.

FIG. 2 is a view showing the level of the pumping voltage VPP generated from the conventional internal voltage generator shown in FIG. 1.

When the level of the pumping voltage VPP is lower than that of a target voltage (e.g., 3.4V), the internal voltage generator in FIG. 1 allows all of the charge pumping units 120 to 180 to be operated, thereby increasing the level of the pumping voltage VPP.

Accordingly, if the level of the pumping voltage VPP is any lower than the level of the target voltage (3.4V), all of the charge pumping units 120 to 180 perform the pumping operation even when the level of the pumping voltage VPP substantially reaches the level of the target voltage (3.4V) through two pumping operations as shown in FIG. 2. Therefore, the level of the pumping voltage VPP is unnecessarily raised.

Raising the level of the pumping voltage VPP above the desired level causes unnecessary consumption of currents. Moreover, this may result in the decrease of the supply voltage (VDD) of peripheral circuits, thereby causing malfunction of the peripheral circuits.

### SUMMARY OF THE INVENTION

Embodiments of the present invention are directed to providing an internal voltage generator of a semiconductor memory device for generating pumping voltages (VPP, VBB, etc.) as internal voltages, which is capable of preventing the level of the pumping voltage from unnecessarily increasing (in a case of VPP) or unnecessarily decreasing (in a case of VBB) due to unnecessary charge pumping operations.

In accordance with an aspect of the present invention, there is provided an internal voltage generator of a semiconductor memory device includes a plurality of charge pumping units for generating a pumping voltage by performing a charge pumping operation according to a plurality of pumping enable signals, and a pumping controller for controlling a number of the pumping enable signals to be activated according to a level of a fed-back pumping voltage.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view showing a conventional internal voltage generator for generating a pumping voltage in a semiconductor memory device;

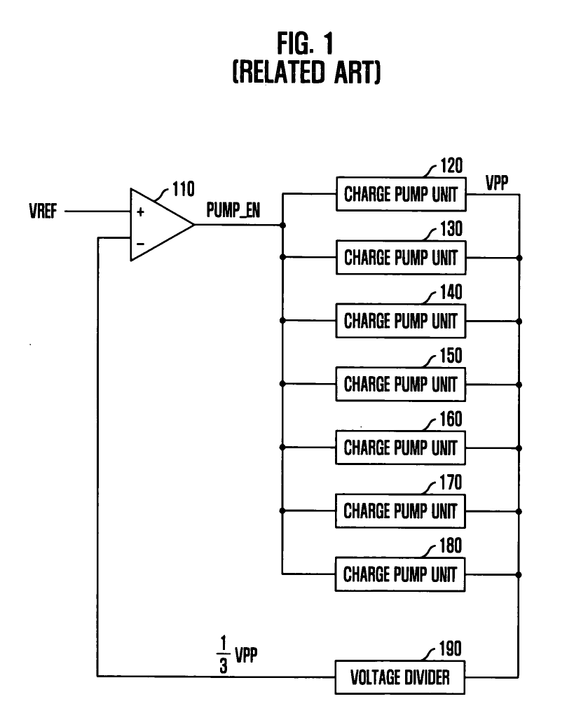

FIG. 2 is a view showing the level of the pumping voltage (VPP) generated from the conventional internal voltage generator shown in FIG. 1;

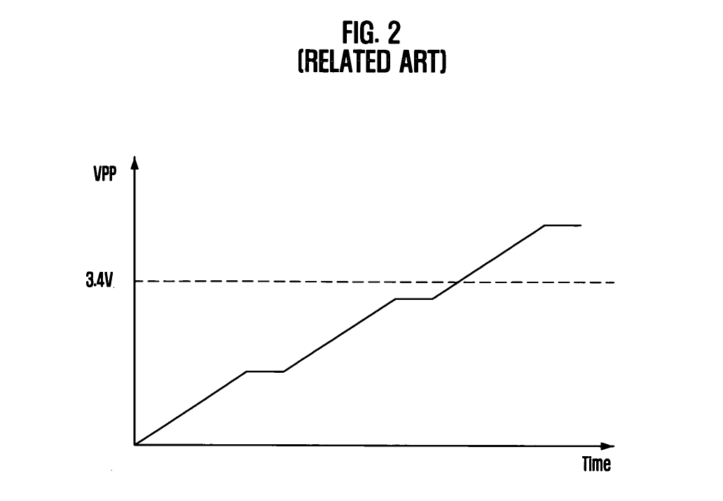

FIG. 3 is a view showing an internal voltage generator of a semiconductor memory device according to an embodiment of the present invention;

FIG. 4 is a view showing the pumping controller of FIG. 3 for generating a high voltage (VPP) according to an embodiment of the present invention;

FIG. 5 is a view showing the level of a high voltage (VPP) in case that the internal voltage generator shown in FIG. 3 generates the high voltage; and

FIG. 6 is a view showing the pumping controller in FIG. 3 for generating a negative voltage (VBB) according to an embodiment of the present invention.

### DESCRIPTION OF THE PREFERRED EMBODIMENTS

Hereinafter, exemplary embodiments of the present invention will be described with reference to accompanying drawings.

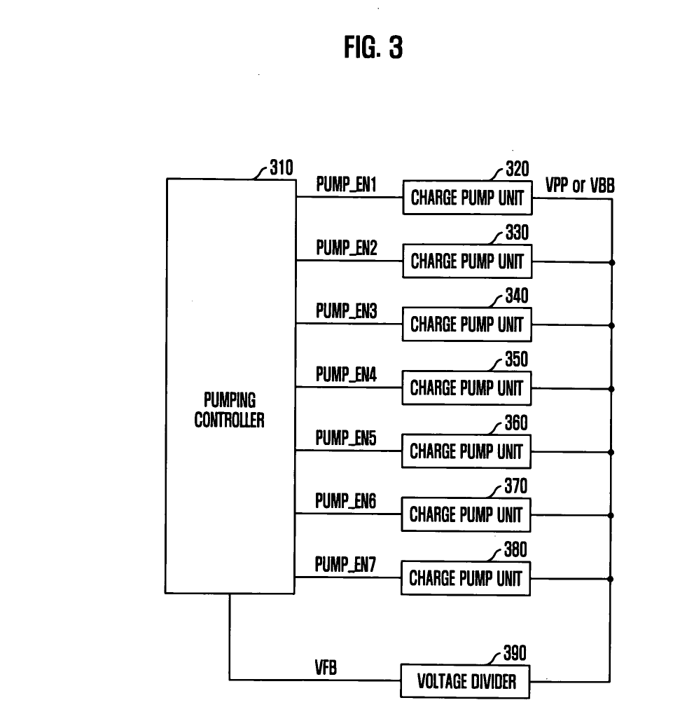

FIG. 3 is a view showing an internal voltage generator of a semiconductor memory device according to an embodiment of the present invention.

As shown in FIG. 3, the internal voltage generator includes a plurality of charge pumping units 320 to 380 and a pumping controller 310.

The charge pumping units 320 to 380 drive a pumping voltage terminal VPP or VBB by performing a charge pumping operation in response to pumping enable signals PUMP_EN1 to 7, respectively. Conventionally, all of the charge pumping units 120 to 180 simultaneously drive the pumping voltage terminal in response to the same pumping enable signal PUMP_EN. However, according to the present invention, pumping enable signals PUMP_EN1 to 7 different from each other are applied to the charge pumping units 320 to 380, respectively, so that all or some of the charge pumping units 320 to 380 can be driven.

If the internal voltage generator generates a high voltage (VPP) as the pumping voltage, the charge pumping units 320 to 380 pump charges to level of the high voltage (VPP) higher than that of a supply voltage (VDD). If the internal voltage generator generates a negative voltage (VBB) as the pumping voltage, the charge pumping units 320 to 380 pump charges to level of the negative voltage (VBB) lower than that of a ground voltage (VSS).

The pumping controller 310 controls the number of the pumping enable signals PUMP_EN1 to 7 to be activated according to the fed-back voltage level of the pumping voltage. If there is great difference between the level of the pumping voltage and the level of a target voltage, the number of pumping enable signals PUMP_EN1 to 7 to be activated increases. If there is little difference between the level of the pumping voltage and the level of the target voltage, the number of pumping enable signals PUMP_EN1 to 7 to be activated decreases.

For example, when the target level of the pumping voltage is 3.4V (in case of the high voltage VPP), all of the pumping enable signals PUMP_EN1 to 7 are activated if the current level of the pumping voltage (VPP) is 1.5V, and five of the pumping enable signals PUMP_EN1 to 7 are activated if the current level of the pumping voltage (VPP) is 2.7V, and one of the pumping enable signals PUMP_EN1 to 7 is activated if the current level of the pumping voltage (VPP) is 3.3V. Accordingly, if the level of the pumping voltage (VPP) is 3.4V or more, none of the pumping enable signals PUMP_EN1 to 7 is activated. In this manner, when the pumping voltage is the negative voltage (VBB), the number of pumping enable signals PUMP_EN1 to 7 to be activated increases as the current level of the negative voltage (VBB) is greatly different from the level of the target voltage.

When the internal voltage generator generates the high voltage (VPP) serving as the pumping voltage, a voltage divider 390 performs voltage division relative to the pumping voltage (VPP) and feeds back the divided pumping voltage to the pumping controller 310. For instance, one third of the pumping voltage (VPP) is fed-back to the pumping controller 310. As described in the conventional invention, since the level of the pumping voltage (VPP) itself is generally higher than that of the supply voltage(VDD), it is difficult to securely perform a comparison operation if the pumping voltage (VPP) is fed-back without performing the voltage division.

Meanwhile, when the internal voltage generator generates the negative voltage (VBB) serving as the pumping voltage, the pumping voltage (VBB) can be fed-back to the pumping controller 310 without performing the voltage division relative to the pumping voltage. Therefore, the voltage divider 390 is not required. The reason for this is that when detecting the level of the negative voltage (VBB), the pumping controller 310 employs a detecting scheme different from the detecting scheme for the high voltage (VPP).

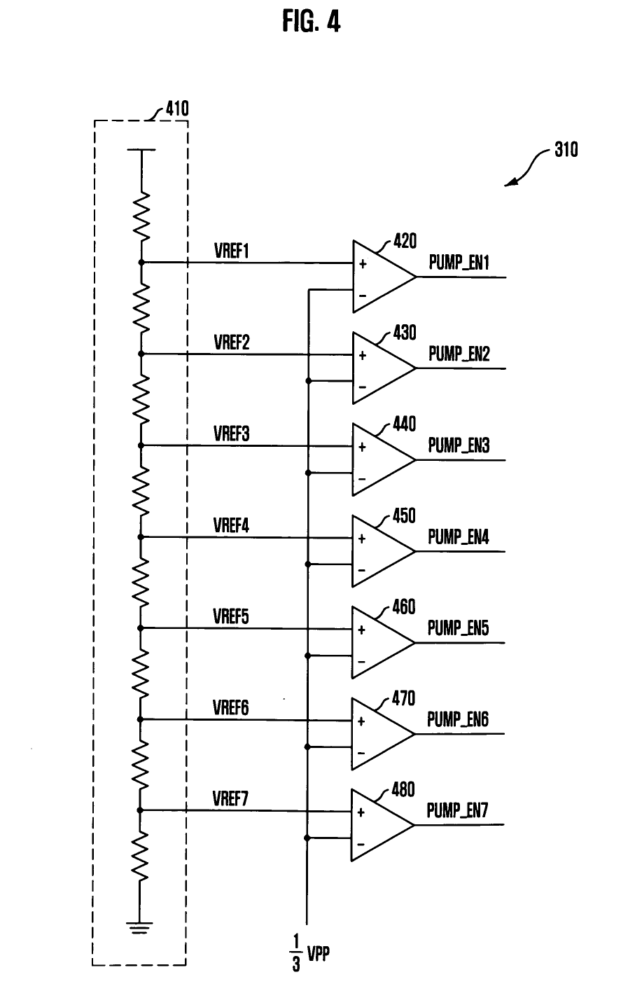

FIG. 4 is a view showing the pumping controller of FIG. 3 for generating the high voltage (VPP) according to an embodiment of the present invention.

When the internal voltage generator generates the high voltage (VPP) serving as the pumping voltage, the pumping controller 310 includes a reference voltage generating unit 410 and a plurality of comparison units 420 to 480. The reference voltage generating unit 410 generates a plurality of reference voltages VREF1 to 7 having different levels from each other. The comparison units 420 to 480 compare one of the reference voltages VREF1 to 7 with a fed-back pumping voltage ⅓*VPP, and output the corresponding pumping enable signals PUMP_EN1 to 7.

The reference voltage generating unit 410 generates the reference voltages VREF1 to 7 having different levels by dividing a predetermined voltage. The predetermined voltage can include the supply voltage (VDD) or a reference voltage which is generated from a different circuit in the semiconductor memory device.

Each comparison unit 420 to 480 compares the reference voltage VREF1 to 7 that each receives with the fed-back pumping voltage ⅓*VPP, and outputs the corresponding pumping enable signal PUMP_EN1 to 7.

When the fed-back pumping voltage ⅓*VPP is lower than the reference voltage VREF1, the comparison unit 420 enables the pumping enable signal PUMP_EN1 in a ‘high’ state to be output. When the fed-back pumping voltage ⅓*VPP is lower than the reference voltage VREF2, the comparison unit 430 enables and outputs the pumping enable signal PUMP_EN2 in the ‘high’ state. In this manner, comparison units 420 to 480 enable the corresponding pumping enable signal PUMP_EN1 to 7 on the basis of their own reference. A common comparator can be used as the comparison units 420 to 480.

If the fed-back pumping voltage ⅓*VPP is between the reference voltage VREF2 and the reference voltage VREF3, only the pumping enable signal PUMP_EN1 and the pumping enable signal PUMP_EN2 are enabled. If the fed-back pumping voltage terminal ⅓*VPP is between the reference voltage VREF4 and the reference voltage VREF5, the pumping enable signals PUMP_EN1 to 4 are enabled. In this manner, the number of the pumping enable signals PUMP_EN1 to 7 that are enabled is controlled according to the level of the fed-back pumping voltage ⅓*VPP.

Therefore, the number of the charge pumping units 320 to 380 that are enabled is determined according to the level of the pumping 15 voltage terminal. Thus, as the level of the pumping voltage (e.g., VPP) approaches that of the target voltage (e.g., 3.4V), fewer of the charge pumping units 320 to 380 are operated so that the level of the pumping voltage is prevented from exceeding the target voltage, thereby preventing unnecessary current consumption.

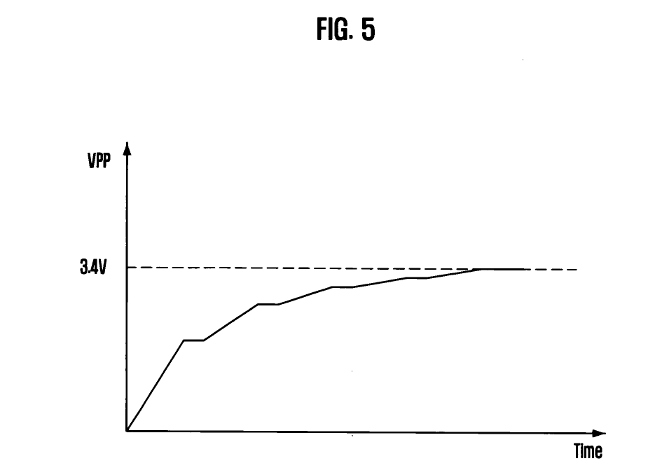

FIG. 5 is a view showing the level of the high voltage VPP in case the internal voltage generator shown in FIG. 3 generates the high voltage.

Referring to FIG. 5, it can be recognized that as time elapses, the high voltage VPP generated from the internal voltage generator converges into the target voltage (e.g., 3.4V) without exceeding the target voltage. This is different from the conventional internal voltage generator, in which the level of the high voltage VPP unnecessarily exceeds the target voltage.

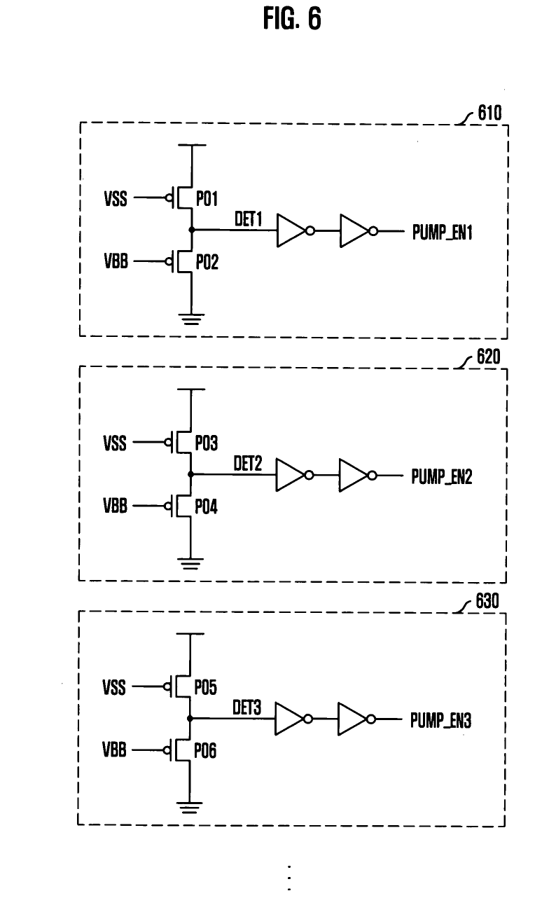

FIG. 6 is a view showing the pumping controller in FIG. 3 for generating a negative voltage (VBB) according to an embodiment of the present invention.

When the internal voltage generator generates the negative 5 voltage VBB (a minus voltage below a ground voltage) as the pumping voltage, the pumping controller 310 includes a plurality of voltage detection units 610 to 630. If a fed-back pumping voltage, i.e., the negative voltage VBB, exceeds corresponding predetermined voltages, the voltage detection units 610 to 630 output corresponding pumping enable signals PUMP_EN1 to 3.

The voltage detection units 610 to 630 enable and output the corresponding pumping enable signals PUMP_EN1 to 3 on the basis different from each other. For example, when the negative voltage VBB is −0.5V or more, the voltage detection unit 610 enables the corresponding pumping enable signal PUMP_EN1, and when the negative voltage VBB is −0.7V or more, the voltage detection unit 620 enables the corresponding pumping enable signal PUMP_EN2. In this manner, the number of the enabled pumping enable signals PUMP_EN1 to 3 can be controlled according to the level of the negative voltage VBB, similar to the pumping controller 310 used for detecting the level of the high voltage VPP shown in FIG. 4.

The voltage detection unit 610 to 630 respectively include first transistors P01, P03 and P05, which have a gate for receiving a ground voltage VSS, and second transistors P02, P04 and P06, which have a gate for receiving a fed-back pumping voltage VBB. Each voltage detection unit 610 to 630 detects the level of the fed-back pumping voltage VBB by using variation in resistance ratios between the first transistors P01, P03 and P05 and the second transistors P02, P04 and P06, and outputs the corresponding pumping enable signal PUMP_EN. In addition, the first transistors P01, P03 and P05 and the second transistors P02, P04 and P06 in each voltage detection unit 610 to 630 have different basic resistance ratios.

The transistors P01 and P02 of the voltage detection unit 610 operate in a linear region, and serves as resistors to perform the voltage division relative to the high voltage (e.g., VDD) and the low voltage (e.g., VSS). If the fed-back pumping voltage VBB has a small absolute value (which means that the level of negative voltage is high), the resistance of the transistor P02 is increased and a potential of a node DET1 rises, thereby enabling and outputting the pumping enable signal PUMP_EN1 in a ‘high’ state. If the fed-back pumping voltage VBB has a large absolute value (which means that the level of negative voltage is low), the resistance of the transistor P02 is decreased and a potential of a node DET1 is dropped, thereby disabling and outputting the pumping enable signal PUMP_EN1 in a ‘low’ state.

The voltage detection units 620 and 630 operate in the same manner as the voltage detection unit 610, in which the voltage detection units 620 and 630 enable/disable the pumping enable signals PUMP_EN2 to 3. However, each voltage detection unit 610 and 630 is designed in such a manner that the basic resistance ratios of the two transistors therein have different values, so the levels of the negative voltage VBB enabling the pumping enable signals PUMP_EN1 to 3 are different from each other. Therefore, the number of enabled pumping enable signals PUMP_EN1 to 3 can be controlled according to the level of the negative voltage VBB.

If the pumping enable signals PUMP_EN1 to 3 are generated in the above manner, the number of the pumping enable signals PUMP_EN1 to 3 to be enabled are increased when the level of the negative voltage VBB is high, and the number of the pumping enable signals PUMP_EN1 to 3 to be enabled is decreased when the level of the negative voltage VBB is low. Accordingly, unnecessary consumption of the current is prevented when generating the negative voltage VBB.

An internal voltage generator of a semiconductor memory device according to the present invention increases the number of charge pumping units that are operated when the current level of a pumping voltage is greatly different from the level of a target voltage, and decreases the number of charge pumping units that are operated when the current level of a pumping voltage is slightly different from the level of a target voltage. Accordingly, since charge pumping operations may not be unnecessarily performed, the efficiency of current consumption is improved when generating the internal voltages.

Although preferred embodiments of the present invention have been disclosed for illustrative purposes, those skilled in the art will appreciate that various modifications, additions and substitutions are possible, without departing from the scope and spirit of the invention as defined in the accompanying claims.

What is claimed is:

1. An internal voltage generator of a semiconductor memory device, comprising:
a plurality of charge pumping units for generating a pumping voltage by performing a charge pumping operation according to a plurality of pumping enable signals; and
a pumping controller for controlling a number of the pumping enable signals to be activated according to a level of a fed-back pumping voltage.

2. The internal voltage generator of claim 1, wherein the pumping controller includes:
a reference voltage generating unit for generating a plurality of reference voltages having different levels from each other; and
a plurality of comparison units for comparing one of the reference voltages with the fed-back pumping voltage to output a corresponding pumping enable signal.

3. The internal voltage generator of claim 2, wherein the reference voltage generating unit generates the reference voltages by dividing a predetermined voltage.

4. The internal voltage generator of claim 1, wherein the fed-back pumping voltage is generated by dividing the pumping voltage.

5. The internal voltage generator of claim 1, wherein the pumping controller includes a plurality of voltage detection units for outputting corresponding the pumping enable signals as the fed-back pumping voltage exceeds a predetermined voltage.

6. The internal voltage generator of claim 5, wherein the voltage detection units each include a first transistor having a gate for receiving a ground voltage and a second transistor having a gate for receiving the fed-back pumping voltage, wherein basic resistance ratios between the first transistor and the second transistor in each of the voltage detection units are different from each other.

7. The internal voltage generator of claim 6, wherein each voltage detection unit detects the level of the fed-back pumping voltage by using variations of the resistance ratio between the first transistor and the second transistor to output the corresponding pumping enable signal.
